(19) United States
(12) Patent Application Publication
(10) Pub. No.: US 2009/0308645 A1
(43) Pub. Date: Dec. 17, 2009

(54) Printed circuit board and manufacturing method thereof

(75) Inventors: Kwi-Jong Lee, Hwaseong-si (KR); Dong-Hoon Kim, Seongnam-si (KR); Young-Il Lee, Anyang-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., SUWON (KR)

(21) Appl. No.: 12/318,963

(22) Filed: Jan. 13, 2009

(30) Foreign Application Priority Data
Jun. 17, 2008 (KR) 10-2008-0056670

(51) Int. Cl. H05K 1/09; B05D 5/12; H05K 1/03

(52) U.S. Cl. 174/257; 427/97.3; 174/255

(57) ABSTRACT

Disclosed are a printed circuit board and a manufacturing method thereof. The printed circuit board having a circuit pattern formed therein includes a substrate having a groove formed therein, the groove corresponding to the circuit pattern; a first circuit pattern formed inside the groove; and a second circuit pattern formed on the first circuit pattern, the second circuit pattern filling up the groove.

### CROSS-REFERENCE TO RELATED APPLICATIONS

This application claims the benefit of Korean Patent Application No. 10-2008-0056670, filed with the Korean Intellectual Property Office on Jun. 17, 2008, the disclosure of which is incorporated herein by reference in its entirety.

### BACKGROUND

1. Technical Field

The present invention relates to a printed circuit board and a manufacturing method thereof.

2. Description of the Related Art

In the past, a sputtering method or a plating method has been used to form a circuit pattern in the groove formed in a substrate.

When a circuit pattern is formed on a substrate having a groove formed therein by the sputtering method, a metal layer is formed not only on the groove but on the entire surface of the substrate. Therefore, after forming the metal layer on the entire surface of the substrate, the metal layer formed on the area other than the groove is removed. The metal layer can be removed through a chemical-mechanical polishing (CMP) process. Such a process of removing the metal layer brings about a waste of metal material and the chemical-mechanical polishing process is not suitable for a fine circuit pattern.

In the plating method, when the substrate is made of a nonconductor, a circuit pattern can be formed by an additive method. In this case, after a surface treatment is performed by means of a pretreatment agent including palladium (Pd) ion, chemical plating is performed. However, there is a problem that it is not possible to selectively treat the surface through the palladium pretreatment agent. With respect to the problem, like the sputtering method mentioned above, a selective etching process should be done through use of the chemical-mechanical polishing (CMP) process or a photosensitive film.

Additionally, without the surface treatment, an adhesive strength between the circuit pattern and the substrate cannot be strengthened through the sputtering method or the plating method.

### SUMMARY

The present invention provides a printed circuit board that has a circuit pattern formed thereon having an excellent adhesive strength to the substrate and excellent electrical conductivity, and provides a manufacturing method thereof.

An aspect of the present invention features a method of manufacturing a printed circuit board having a circuit pattern formed thereon. The method in accordance with an embodiment of the present invention can include: providing a substrate having a groove formed therein, the groove corresponding to the circuit pattern; forming a first circuit pattern inside the groove by filling the groove with conductive ink; and forming a second circuit pattern on the first circuit pattern such that the groove is completely filled up.

The forming of the first circuit pattern can be performed by filling the groove with conductive ink and then sintering the conductive ink.

The forming of the second circuit pattern can be performed by plating the first circuit pattern and filling an interior space of the groove with a plating material.

Another aspect of the present invention features a printed circuit board having a circuit pattern formed thereon. The printed circuit board in accordance with an embodiment of the present invention can include: a substrate having a groove formed therein, the groove corresponding to the circuit pattern; a first circuit pattern formed inside the groove; and a second circuit pattern formed on the first circuit pattern, the second circuit pattern filling up the groove.

The first circuit pattern can be formed by filling the groove with conductive ink.

The second circuit pattern can be formed by plating the first circuit pattern and filling an interior space of the groove with a plating material.

### BRIEF DESCRIPTION OF THE DRAWINGS

FIG. 1 shows a flowchart of a manufacturing method of a printed circuit board according to an embodiment of the present invention.

FIGS. 2 to 6 show a manufacturing process of a printed circuit board according to an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, embodiments of a printed circuit board and a manufacturing method thereof in accordance with the present invention will be described in detail with reference to the accompanying drawings. In description with reference to accompanying drawings, the same reference numerals will be assigned to the same or corresponding elements, and repetitive descriptions thereof will be omitted.

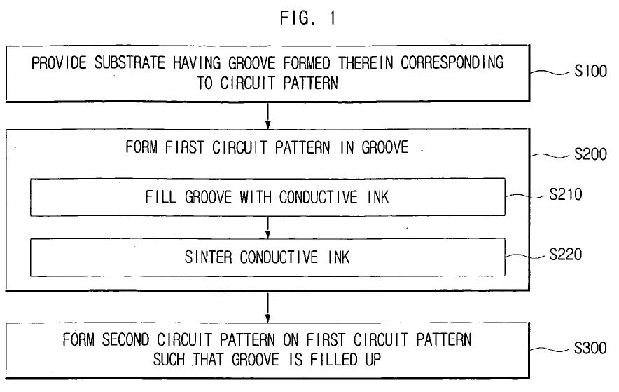

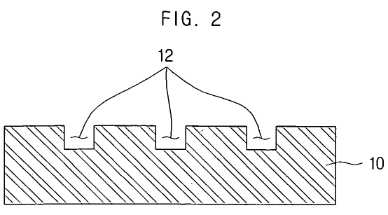

FIG. 1 shows a flowchart of a manufacturing method of a printed circuit board according to an embodiment of the present invention. FIGS. 2 to 6 show a manufacturing process of a printed circuit board according to an embodiment of the present invention. Referring to FIGS. 2 to 6, illustrated are a substrate 10, a groove 12, a first circuit pattern 20, conductive ink 22, a second circuit pattern 30 and a circuit pattern 40.

According to an embodiment of the present invention, provided is a substrate 10 having a groove 12 formed on one side thereof as shown in FIG. 2 (S100). The groove 12 has a negative pattern dented into the inside of the substrate from the surface of the substrate 10. As viewed from the upper side of the substrate, the groove has a shape corresponding to that of the circuit pattern 40 designed to be formed on the substrate. That is, the groove has a shape of the circuit pattern and is formed on the surface of the substrate 10 in the shape of the negative pattern.

Here, the substrate 10 can be made of an insulation substrate or a glass material. The groove 12 can be formed by performing an imprinting process or a partial etching process on the surface of the substrate. It is possible to provide a substrate having a groove corresponding to the circuit pattern 40 by means of various methods including the methods mentioned above.

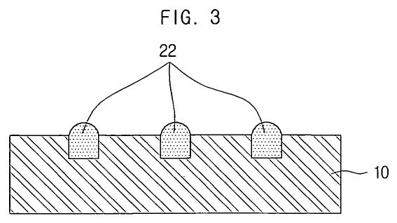

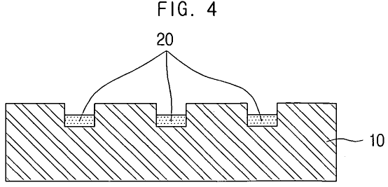

Subsequently, a first circuit pattern 20 is formed inside the groove 12 as shown in FIGS. 3 and 4 (S200). In the embodiment of the present invention, the first circuit pattern 12 is formed by filling the groove 12 with conductive ink 22. The conductive ink includes a metal particle, a solution and an organic additive, and can be a viscous ink being used in a screen printing process or an inkjet printing process. Copper (Cu) nano-particle or silver (Ag) nano-particle can be used as the metal particle.

The conductive ink 22 in the description of the present invention can be understood to include liquefied ink including the metal particle, a conductive material having a paste-typed or a conductive material in a semi-hardened state, and the like. The conductive ink is able to form a metal pattern by sintering and hardening the included metal particle. As such, the viscous conductive material in the liquefied state or paste state is included in the range of the conductive ink 22 of the present invention.

According to the embodiment of the present invention, as shown in FIG. 3, the groove is filled with the conductive ink by means of a method of printing the conductive ink 22 including the metal particle inside the groove 12 (S210). Through the inkjet printing method or the screen printing method, the conductive ink can be printed only in the area having the groove formed therein. The groove can be selectively filled up with the conductive ink by using a method of coating the inside of the groove with the conductive ink.

The conductive ink 22 is compounded with a metal particle, a solution and an additive, and the like. The volume occupied by the metal particle can be less than approximately 40% of the volume of the entire ink. In particular, when nano-ink includes a metal nano particle, the volume of the metal particle can be less than approximately 10% of the volume of the entire ink.

After printing the conductive ink 22 in the groove 12, the conductive ink is sintered by performing a thermal process (S220). As described above, the conductive ink 22 can include the metal particle of which volume is within at most 50% of the volume thereof. Accordingly, after sintering, a first circuit pattern 20 is formed inside the groove 12 as shown in FIG. 4.

Referring to FIGS. 3 and 4, as the first circuit pattern 20 having a volume less than that of the conductive ink 22 is formed, the first circuit pattern is formed by not entirely filling up the entire interior space of the groove 12. As mentioned above, the metal particle occupies a part of the entire volume of the conductive ink. Therefore, the first circuit pattern formed by filling the groove with the conductive material cannot fill up the entire groove 12.

According to an embodiment of the present invention, while disclosed is a method of sintering the conductive ink 22, it is also possible to form the first circuit pattern 20 inside the groove 12 by air-drying the conductive ink 22 as shown in FIG. 4.

As described above, it is possible to provide the first circuit pattern 20 formed through growth of the metal particle in the conductive ink by sintering or drying the conductive ink 22. According to the embodiment of the present invention, the first circuit pattern is directly adhered to the inside of the groove 12 and formed. The first circuit pattern has an advantage of being formed without a surface treatment process of the substrate 10.

In this case, as a ratio between the metal particle and the additive of the conductive ink 22 used in the process of forming the first circuit pattern 20 is adjusted, the adhesive strength and the electrical conductivity of the first circuit pattern 20 are changeable. In other words, if a ratio (R) of content of the metal particle/the additive is low, the adhesive strength is increased while the electrical conductivity is reduced. On the contrary, if a ratio (R) of content of the metal particle/the additive is high, the adhesive strength is more or less reduced while the electrical conductivity is increased.

The first circuit pattern 20 formed during the process of sintering or drying the conductive ink 22 has a sparse particle structure as compared with that of the metal pattern formed by the plating method. Accordingly, there is a limit in representing the electrical conductivity of the level of the metal pattern formed by the plating method.

According to the embodiment of the present invention, the first circuit pattern 20 performs a function of an adhering layer to adhere the circuit pattern 40 to the surface of the substrate 10 with reliability. Therefore, in accordance with the design intent, the first circuit pattern having a predetermined adhesive strength can be formed inside the groove 12.

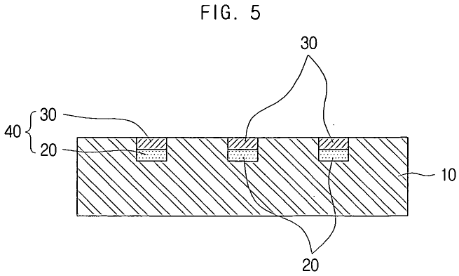

As shown in FIG. 5, a second circuit pattern 30 is formed on the first circuit pattern 20 such that the groove 12 is filled up (S300). The interior space of the groove is filled with the second circuit pattern 30, which could not be filled up with the first circuit pattern. Here, the second circuit pattern can be formed by plating the first circuit pattern.

It is possible to selectively form the plating material only inside the groove 12 instead of on the entire surface of the substrate 10 by plating the first circuit pattern 20. The interior space of the groove 12 is filled with the plating material formed on the first circuit pattern. The plating material becomes the second circuit pattern 30 formed by filling up the groove. Accordingly, it is possible to form a second circuit pattern having both a dense metal particle structure and excellent electrical conductivity in comparison with those of the first circuit pattern.

A circuit pattern 40 having excellent electrical conductivity as a whole can be formed by forming the second circuit pattern 30 on the first circuit pattern 20. Moreover, the circuit pattern 40 filling up the entire interior space of the groove 12 can be formed.

According to an embodiment of the present invention, the second circuit pattern filling up the entire groove 12 as shown in FIG. 5 can be formed by repeating plating on the first circuit pattern 20. The plating process is performed such that the upper side of the second circuit pattern 30 is formed to have the same height as that of the surface of the substrate 10.

The plating process can be performed on the first circuit pattern 20 by an electroless plating method or an electrolytic plating method. The electroless plating can be performed either when the first circuit pattern is not overall connected or when the electrical conductivity is low. On the contrary, both when the first circuit pattern is all connected and when the electrical conductivity is high, the electrolytic plating can be effective for reducing the time for performing the process. The plating method can be selected according to the shape and property of the first circuit pattern.

According to the embodiment of the present invention, the circuit pattern 40 buried inside the groove 12 can be formed as shown in FIG. 5. In FIG. 5, the first circuit pattern 20 is formed inside the groove of the substrate 10. The second circuit pattern 30 filling up the groove 12 is formed on the first circuit pattern.

The first circuit pattern 20 having a high adhesive strength is formed inside the groove. The second circuit pattern 30 having high electrical conductivity is formed on the first circuit pattern. As a result, the entire circuit pattern 40 is reliably adhered to the substrate 10 and has high electrical conductivity.

The circuit pattern 40 is formed by being buried in the groove 12 of the substrate 10. Consequently, the shape of the circuit pattern 40 is reliably protected so that a space between the patterns is reliably insulated and a fine pattern and a fine pitch can be implemented.

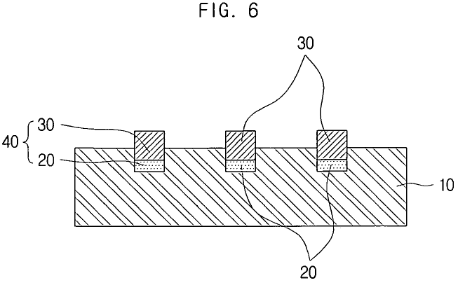

Through adjusting the time for performing the plating the first circuit pattern 20, the height of the second circuit 30 can be adjusted. As shown in FIG. 5, the plating is continued in a state where the second circuit pattern is formed to have the same height as that of the surface of the substrate 10. Consequently, the plating material is continuously formed and the upper side of the second circuit pattern can be higher than the surface of the substrate 10 as shown in FIG. 6. That is, the thickness of the entire circuit pattern 40 can be adjusted according to the time for performing the plating.

According to the embodiment of the present invention, the thickness of the circuit pattern 40 can be adjusted in accordance with the design objective and intent of the circuit pattern 40 designed to be formed on the substrate 10. It is also possible to form the circuit pattern 40 having at once the excellent adhesive strength and excellent electrical conductivity. There is an advantage that a special surface treatment for the substrate 10 is not required when forming the first circuit pattern 20.

In short, according to the embodiment of the present invention, as a result of performing the plating process after both filling the groove 12 of the substrate 10 with the conductive ink 22 including the metal particle by a printing method or a coating method and sintering the conductive ink, it is possible not only to completely fill up a certain groove 12 but to form the circuit pattern 40 higher than the surface of the substrate 10 if necessary. The aforesaid method of forming the circuit pattern can be used as a method of increasing the thickness of the circuit pattern as well as can show the possibility of selectively plating the surface of the substrate. Additionally, through the method of forming the circuit pattern, preprocessing like surface treatment of a material is not required before forming the circuit pattern 40.

While certain embodiment of the present invention has been described, it shall be understood by those skilled in the art that various changes and modification in forms and details may be made without departing from the spirit and scope of the present invention as defined by the appended claims.

Numerous embodiments other than embodiments described above are included within the scope of the present invention.

What is claimed is:

1. A method of manufacturing a printed circuit board having a circuit pattern formed therein, the method comprising:
providing a substrate having a groove formed therein, the groove corresponding to the circuit pattern;
forming a first circuit pattern inside the groove by filling the groove with conductive ink; and
forming a second circuit pattern on the first circuit pattern such that the groove is completely filled up.

2. The method of claim 1, wherein the forming of the first circuit pattern is performed by filling the groove with conductive ink and then sintering the conductive ink.

3. The method of claim 1, wherein the forming of the second circuit pattern is performed by plating the first circuit pattern and filling an interior space of the groove with plating material.

4. A printed circuit board having a circuit pattern formed therein, the printed circuit board comprising:
a substrate having a groove formed therein, the groove corresponding to the circuit pattern;
a first circuit pattern formed inside the groove; and
a second circuit pattern formed on the first circuit pattern, the second circuit pattern filling up the groove.

5. The printed circuit board of claim 4, wherein the first circuit pattern is formed by filling the groove with conductive ink.

6. The printed circuit board of claim 4, wherein the second circuit pattern is formed by plating the first circuit pattern and filling an interior space of the groove with a plating material.
